(19) United States
(12) Patent Application Publication
(10) Pub. No.: US 2025/0155809 A1
(43) Pub. Date: May 15, 2025

(54) PHOTORESIST MATERIAL AND METHOD FOR LITHOGRAPHY

(71) Applicant: Taiwan Semiconductor Manufacturing Company, LTD., Hsinchu (TW)

(72) Inventors: Chun-Chih Ho, Taichung (TW); Ching-Yu Chang, Yuansun (TW)

(21) Appl. No.: 18/389,267

(22) Filed: Nov. 14, 2023

(51) Int. Cl. G03F 7/039; G03F 7/004; G03F 7/40

(52) U.S. Cl. CPC G03F 7/0392; G03F 7/0045; G03F 7/40

(57) ABSTRACT

A photoresist composition comprises an acid-cleavable copolymer formed from oligomers in a backbone or an arm of the copolymer. Each oligomer comprises an acid-labile group; a first comonomer having an acidic leaving substituent; and at least one of a second comonomer having a proton donating substituent or a third comonomer having a polar substituent. The copolymer may also include a RAFT (Reversible Addition Fragmentation chain Transfer) chain transfer agent. Upon exposure to radiation, acid is generated that cleaves the copolymer. This improves the line edge roughness (LER) of the photoresist layer while maintaining good coating properties.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

High-resolution lithography processes are needed to obtain smaller feature sizes. An example of one such process is extreme ultraviolet (EUV) lithography, which uses wavelengths of about 10 nanometers (nm) to about 100 nm. Further improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a table of acid-labile groups and their degradation products.

FIG. 2 is a flow chart illustrating a method for forming an acid-cleavable copolymer, in accordance with some embodiments.

FIG. 3 is a first illustrative example for synthesizing an acid-cleavable copolymer of the present disclosure.

FIG. 4 is a second illustrative example for synthesizing an acid-cleavable copolymer of the present disclosure.

FIG. 5 is a third illustrative example for synthesizing an acid-cleavable copolymer of the present disclosure.

FIG. 6 is a fourth illustrative example for synthesizing an acid-cleavable copolymer of the present disclosure.

FIG. 7 is a fifth illustrative example for synthesizing an acid-cleavable copolymer of the present disclosure. This copolymer is a star copolymer.

FIG. 8 is an illustration of an acid-cleavable copolymer of the present disclosure containing two to five different monomers, a RAFT chain transfer agent, and an acid-labile group in the backbone of the polymer.

FIG. 9 is a flow chart illustrating a method for preparing a patterned photoresist layer and etching a layer of a semiconducting device, in accordance with some embodiments.

FIG. 10A is a cross-sectional view of a substrate prior to starting the method of FIG. 9.

FIG. 10B is a cross-sectional view of a substrate with a first material layer located upon the substrate, again prior to starting the method of FIG. 9.

FIG. 10C is a cross-sectional view of a substrate with two underlayers applied upon the first material layer, again prior to starting the method of FIG. 9.

FIG. 11 is a cross-sectional view of the substrate with a photoresist layer over the first material layer, and a surface layer over the photoresist layer.

FIG. 12 is a cross-sectional view of the substrate after radiation exposure, with the photoresist layer now including soluble regions and insoluble regions.

FIG. 13 is a cross-sectional view of the substrate after development, with a patterned photoresist layer.

FIG. 14 is a cross-sectional view of the final structure with a patterned first material layer.

FIG. 15 is an illustration of an extreme ultraviolet (EUV) photolithography system for exposing the photoresist layer to EUV radiation, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

As used herein, the term “copolymer” refers to a polymeric molecule derived from two or more monomers, as opposed to a homopolymer, which is a molecule derived from only one monomer.

The term “monomer” refers to a molecule that can react with other monomers to form a polymer. A “repeating unit” is derived from a monomer, and they differ in a known manner in their structure. These two terms may be used interchangeably.

In the present disclosure, the term “oligomer” is used to refer to a group of monomers which have been reacted together. A plurality of oligomers are joined together to form a polymer. It is noted this is somewhat different from conventional usage, where an oligomer and a polymer differ from each other based on their length.

The term “alkyl” refers to a radical composed entirely of carbon atoms and hydrogen atoms which is fully saturated (i.e. does not contain double or triple bonds). The alkyl radical may be linear, branched, or cyclic. The alkyl radical may bond to one or two other atoms, depending on the context in which it is used. For example, both methyl (—CH₃) and methylene (—CH₂—) should be considered alkyl radicals. As used herein, an alkyl radical contains 1 to 8 carbon atoms. An alkyl radical may be substituted.

The term “aryl” refers to an aromatic radical composed entirely of carbon atoms, and optionally hydrogen atoms along the perimeter of the radical. As used herein, an aryl group has from 6 to about 18 carbon atoms. The term “aryl” should not be construed as including substituted aromatic radicals, such as methylphenyl group (7 carbon atoms). The aromatic radical may bond to one or two other atoms, depending on the context in which it is used. For example, both phenyl (—C₆H₅) and phenylene (—C₆H₄—) should be considered aromatic radicals. An aryl radical may be substituted.

The term “carbonyl” refers to a radical of the formula —CO—, where the carbon atom is bonded to two other carbon atoms.

The term “ether” refers to a radical of the formula —O—, where the oxygen atom is bonded to two other carbon atoms.

The term “ester” refers to a radical of the formula —CO—O—, where the carbon atom and the oxygen atom are each bonded to another carbon atom.

The term “amide” refers to a radical of the formula —CO—NH—.

The term “acetal” refers to a radical of the formula —O—CR¹R²—O—, where R¹ is alkyl or substituted alkyl, and R² is either hydrogen, alkyl, or substituted alkyl.

The term “imine” refers to a radical of the formula —N═CR—, where R is hydrogen, alkyl or substituted alkyl.

The term “hydrazone” refers to a radical of the formula —NH—N═CR—, where R is hydrogen, alkyl or substituted alkyl.

The term “oxime” refers to a radical of the formula —O—N═CR—, where R is hydrogen, alkyl or substituted alkyl.

The term “dithioester” refers to a radical of the formula —C(═S)—S—.

The term “trithiocarbonate” refers to a radical of the formula —S—C(═S)—S—.

The term “dithiocarbamate” refers to a radical of the formula —NR—C(═S)—S—, where R is alkyl, substituted alkyl, aryl, or substituted aryl.

The term “xanthate” refers to a radical of the formula —O—C(═S)—S—.

The term “carboxyl” refers to a radical of the formula —CO—OR″, where R″ is hydrogen or alkyl or substituted alkyl, and also refers to the salt thereof. The carboxy radical bonds through the carbon atom. It is noted that a carbonate group (—O—CO—OR″) should not be considered a carboxyl group.

The term “amine” refers to a radical of the formula —NR¹R², where R¹ and R² are independently hydrogen, alkyl, or substituted alkyl. This includes monosubstituted radicals (i.e. where R² is hydrogen) and disubstituted radicals (where neither R¹ nor R² are hydrogen).

The term “hydroxy” refers to the —OH radical.

The term “cyano” refers to a radical of the formula —CN.

The term “halogen” refers to a fluorine (F), chlorine (Cl), bromine (Br), or iodine (I) atom.

The term “acrylate” refers to a radical of the formula H₂C=CR¹—CO—OR², where R¹ can be hydrogen, alkyl, or substituted alkyl, and R² can be hydrogen, alkyl, substituted alkyl, aryl, or substituted aryl.

The term “lactone” refers to a cyclic ester.

The term “heterocyclic” refers to a cyclic radical containing at least one heteroatom such as nitrogen, oxygen, phosphorus, or sulfur.

The term “substituted” refers to at least one hydrogen atom on the named radical being substituted with another functional group. An exemplary substituted alkyl group is a perhaloalkyl group, wherein one or more hydrogen atoms in an alkyl group are replaced with halogen atoms.

The term “up to X” is used in this disclosure to indicate an amount of a given material. This term should be construed to require the given material to be present in an amount greater than zero, or in other words to exclude the value zero.

The present disclosure relates to photoresist compositions and methods for using such compositions in photolithographic processes for manufacturing integrated circuits/semiconductor devices. In this regard, photoresist compositions are typically coated onto a substrate, for example by spin-coating, and may also be cured by baking. The photoresist contains a photosensitive material. A mask pattern is used to expose desired portions of the photoresist to radiation, such as ultraviolet light or an electron beam. The photoresist is then developed using a chemical solution (known as developer). The developer removes portions of the photoresist (e.g. exposed portions in a positive-tone photoresist), so that the mask pattern is transferred to the photoresist layer. The patterned photoresist layer can then be used as an etch mask for subsequent etching processes that transfer the pattern to an underlying material layer.

The minimum feature size of the pattern is limited by the light wavelength. Deep ultraviolet (UV) lithography uses a wavelength of 193 nm or 248 nm. Extreme ultraviolet (EUV) light, which spans wavelengths from 124 nanometers (nm) down to 10 nm, is currently being used to provide small minimum feature sizes. At such wavelengths, the photosensitive materials need to use the light as efficiently as possible. The efficiency of the photoresist can be increased using chemical amplification. In a chemically amplified resist or CAR, the photoresist composition includes a photosensitive polymer, a photoacid generator (PAG), and a quencher. Upon exposure to radiation, the PAG generates an acid. The acid cleaves an acid leaving group (ALG) on the polymer to change the solubility of the polymer. This also produces an acid, which can continue the reaction. Such a chain reaction will be terminated only when the acid produced comes in contact with a base, also referred to as a quencher. The balance between the acids and the quencher determines the fidelity of the photoresist pattern, e.g. whether the sidewalls are straight or not. However, low radiation dosages generally lead to poor line width roughness (LWR) and critical dimension uniformity (CDU) due to photon shot noise.

The photoresist compositions of the present disclosure include a photosensitive copolymer. The copolymer can be a linear copolymer or a star copolymer with arms. The copolymer includes acid-labile units in the backbone or arms of the copolymer. When exposed to acid, the copolymer is cleaved, resulting in fragments with significantly reduced molecular weight compared to the original acid-cleavable copolymer. This provides a balance between good coating quality at higher molecular weights and improved line edge roughness (LER) which can counteract poor LWR. The photoresist compositions may further include a photoacid generator (PAG), a quencher, and a solvent if desired.

In particular embodiments of the present disclosure, the acid-cleavable copolymer can be formed from three, four, five, six, or more different monomers. The copolymer is typically made using a living polymerization process such as RAFT (Reversible Addition Fragmentation chain Transfer). As a result, in particular embodiments, the acid-cleavable copolymer is a random copolymer.

In some embodiments, the acid-cleavable copolymer can be a linear copolymer, which contains a single backbone with substituents or pendant groups or sidechains extending therefrom. In other embodiments, the acid-cleavable copolymer is a star copolymer with arms. The star copolymer is formed from a spacer core from which three or more arms extend. Each arm has the structure of a linear copolymer, and the specific order of monomers in each arm may differ from that of the other arms.

In some specific embodiments of the present disclosure, the acid-cleavable copolymer has the general structure illustrated in one of Formulas (I)-(V) below:

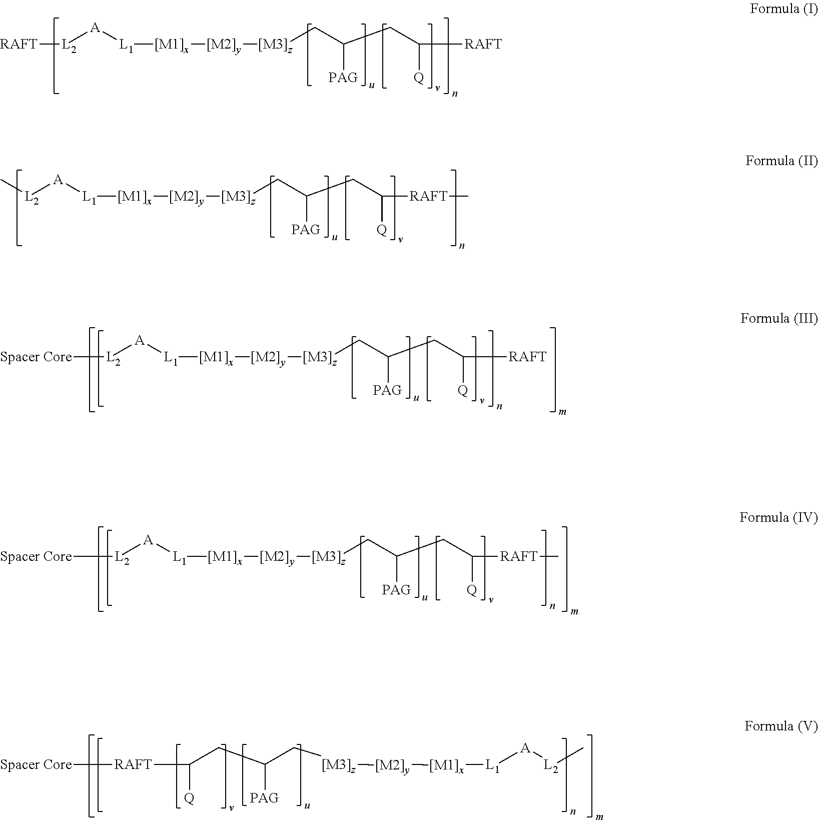

wherein RAFT is a RAFT chain transfer agent;
A represents an acid-labile group;
L₁ and L₂ are independently linking groups;
M1 is a first comonomer that has an acid-leaving substituent;
M2 is a second comonomer that has a proton donating substituent;
M3 is a third comonomer that has a polar substituent;
PAG represents a photoacid generating substituent of a fourth comonomer;
Q represents a quenching substituent of a fifth comonomer;
x represents a molar amount of the first comonomer in the oligomer;
y represents a molar amount of the second comonomer in the oligomer;
z represents a molar amount of the third comonomer in the oligomer;
u represents a molar amount of the fourth comonomer in the oligomer;
v represents a molar amount of the fifth comonomer in the oligomer;
wherein x+y+z+u+v=100%;
n is the number of oligomers in the copolymer; and
m is the number of arms in the star copolymer.
   Again, it should be noted that the acid-cleavable copolymer is typically a random copolymer, and the notation of Formulas (I)-(V) is used for convenience and ease of understanding, and should not be interpreted as requiring the copolymer to be a block copolymer.

As mentioned above, the acid-cleavable copolymer may be formed via RAFT polymerization. The RAFT chain transfer agent may thus be part of the final copolymer. The RAFT chain transfer agent may be a dithioester, a trithiocarbonate, a dithiocarbamate, or a xanthate. These four structures are illustrated below:

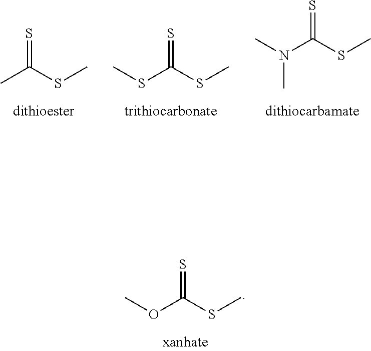

Formula (I) and (II) are two different embodiments of acid-cleavable linear copolymers. In Formula (I), the RAFT chain transfer agent serves as end-caps to the copolymer. In Formula (II), the RAFT chain transfer agent is part of the oligomer that repeats to make up the copolymer. Formulas (III), (IV), and (V) are three different embodiments of acid-cleavable star copolymers. In Formula (III), the RAFT chain transfer agent serves as an end-cap to each arm of the copolymer. In Formulas (IV) and (V), the RAFT chain transfer agent is part of the oligomer that repeats to make up each arm of the copolymer. These two formulas differ in which oligomer attach to the spacer core. As will be explained further, these five formulas may occur depending on the complete structure of the RAFT initiator.

It should be noted that the comonomers are located between the acid-labile group A and the RAFT chain transfer agent as a result of the polymerization technique. It should also be noted that in some embodiments where the RAFT chain transfer agent acts as an end-cap, the RAFT chain transfer agent can be removed and replaced with a different end-cap using known techniques.

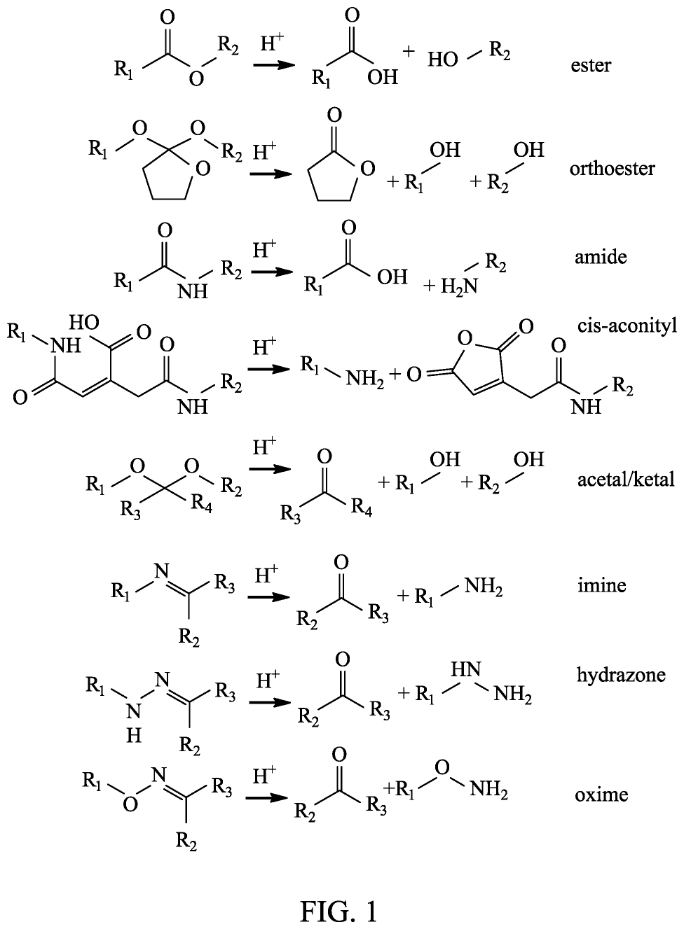

The acid-labile group A is part of the backbone in Formula (I) and Formula (II). The acid-labile group A is part of each arm in Formulas (III)-(V). When exposed to acid, the acid-labile group is cleaved. In particular embodiments, the acid-labile group present in the acid-cleavable copolymer is an ester, an amide, an acetal, an imine, a hydrazone, or an oxime. General formulas for these acid-labile groups are illustrated in FIG. 1, as well as their degradation products. In this figure, R¹ and R² indicate the remainder of the copolymer, while R³ and R⁴ are independently hydrogen, alkyl, or substituted alkyl.

In FIG. 1, two different examples of esters are illustrated. In the first example, an ester is cleaved into a carboxylic acid and an alcohol. In the second example, the orthoester bond cleaves to form a lactone and two alcohols. Two different examples of amides are also illustrated. In the first example, an amide is cleaved into a carboxylic acid and an amine. In the second example, a cis-aconityl group is cleaved into an amine and a maleamidic amide. It is noted that a ketal is a subset of acetals, and occurs when R² is hydrogen.

Referring back to Formulas (I)-(V), L₁ and L₂ are independently linking groups. As will be discussed further herein, these linking groups may be formed as part of the polymerization process. Examples of such linking groups may include —O—, —S—, an ester group, or a carbonyl group.

M1 represents a first comonomer, which has an acid-leaving substituent. Upon exposure to acid, the acid-leaving substituent is cleaved, which increases the hydrophilicity of the copolymer. Such acid-leaving groups (ALGs) are well known in the art. In some specific embodiments, the first comonomer is an alkyl acrylate or an aryl acrylate. In more particular embodiments, the first comonomer is t-butyl acrylate, which is illustrated below as Formula (M1-a):

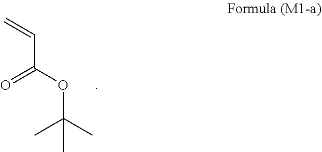

M2 represents a second comonomer, which has a proton donating substituent. This can provide a source of hydrogen for the photoacid generator (PAG). In particular embodiments, the second comonomer is styrene having one or more hydroxy, ether, ester, or carboxyl substituents. In more particular embodiments, the second comonomer is 4-hydroxystyrene, which is illustrated below as Formula (M2-a):

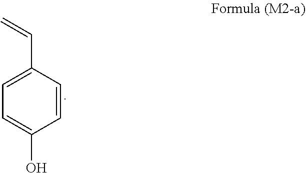

M3 represents a third comonomer, which has a polar substituent. This comonomer adjusts the polarity of the overall copolymer, which affects the solubility of the copolymer in the developer. In particular embodiments, the polar substituent is a heterocyclic group, and in more particular embodiments contains one or more oxygen atoms. In more particular embodiments, the heterocyclic group is a five-membered ring or a six-membered ring, which may be substituted with appropriate substituents. In specific embodiments, the polar substituent is a lactone. The polar substituent may be attached to, for example, an acrylate. One particular example is illustrated below as Formula (M3-a):

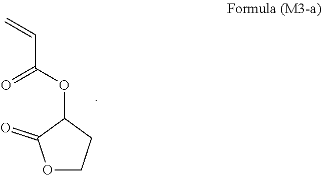

In some embodiments, a fourth comonomer may be present which includes a photoacid generating substituent, identified in Formulas (I)-(V) as PAG. Monomers containing such PAGs are well-known in the art.

Similarly, in some embodiments, a fifth comonomer may be present which includes a quenching substituent, identified in Formulas (I)-(V) as Q. Monomers containing such quenching substituents are well-known in the art.

It should be noted that while a particular monomer may fall within the definition of more than one of the comonomers discussed above, Formulas (I)-(V) should be construed as requiring the presence of different monomers. For example, a particular comonomer cannot be considered to be both M1 and M2.

The variable x represents a molar amount of the first comonomer in the oligomer; y represents a molar amount of the second comonomer in the oligomer; z represents a molar amount of the third comonomer in the oligomer; u represents a molar amount of the fourth comonomer in the oligomer; and v represents a molar amount of the fifth comonomer in the oligomer. Together, x+y+z+u+v=100%. In this regard, the molar amount of the RAFT chain transfer agent and the acid-labile group A in the oligomer are not considered when determining these molar amounts, even though they could be considered comonomers.

In the acid-cleavable copolymers of Formulas (I) through (V), the first comonomer M1 is always present. In particular embodiments, x is about 0.15 to about 0.70, or in other words the copolymer contains from about 15 mole % to about 70 mole % of monomer M1. In some more specific monomers, x is from about 0.20 to about 0.50. However, other values and ranges are also within the scope of this disclosure.

Continuing, at least one of the second comonomer M2 and the third comonomer M3 is always present. It is contemplated that only M2 may be present, or only M3 may be present, or both M2 and M3 are present in the copolymer. When present, y is up to about 0.50, or in other words the copolymer may contain up to about 50 mole % of monomer M2. When present, z is up to about 0.70, or in other words the copolymer may contain up to about 70 mole % of monomer M3. However, other values and ranges are also within the scope of this disclosure.

The presence of the fourth comonomer and the fifth comonomer is optional. When present, u is up to about 0.30, or in other words the copolymer may contain up to about 30 mole % of the PAG-containing comonomer. Similarly, when present, v is up to about 0.30, or in other words the copolymer may contain up to about 30 mole % of the quencher-containing monomer. However, other values and ranges are also within the scope of this disclosure.

In some specific embodiments of Formulas (I)-(V), y is 0 and z is greater than 0. In other words, the copolymer contains the first comonomer and the third comonomer.

In other specific embodiments of Formulas (I)-(V), z is 0, y is greater than 0, and both u and v are zero. In other words, the copolymer contains the first comonomer and the second comonomer.

In still other specific embodiments of Formulas (I)-(V), z is 0; and y, u, and v are all greater than 0, and both u and v are zero. In other words, the copolymer contains the first comonomer and the second comonomer, and also contains the fourth comonomer and the fifth comonomer.

The variable n represents the number of oligomers in the copolymer. In particular embodiments, n is from 2 to about 40. Similarly, the variable m is the number of arms in the star copolymer. In particular embodiments, m is from 3 to 12. However, other values and ranges are also within the scope of this disclosure.

In particular embodiments, the spacer core of the star copolymer may be any alkyl or aryl group. For example, the spacer core could be a phenyl group, or could be derived from pentaerythritol, C(CH₂—)₄.

The acid-cleavable copolymers can be prepared using living radical polymerization, in particular RAFT (Reversible Addition Fragmentation chain Transfer). In some particular embodiments, the weight-average molecular weight (Mw) of the acid-cleavable copolymer may be from about 2,000 to about 100,000. In some more specific embodiments, the Mw is from about 10,000 to about 20,000. Due to the use of RAFT, the polydispersity (PDI) of the acid-cleavable copolymer may be very low, and in some particular embodiments is from 1 to about 1.4. These values are for the copolymer prior to cleavage. Other values and ranges are also within the scope of this disclosure.

A RAFT polymerization system usually includes a radical initiator, monomer/comonomer, and the RAFT initiator. A solvent may also be included.

As previously mentioned, the RAFT initiator includes a dithioester, a trithiocarbonate, a dithiocarbamate, or a xanthate chain transfer agent, and also includes two or three additional groups, typically referred to as R and Z groups. The R group is typically selected to be a good homolytic leaving group, so as to initiate and reinitiate polymerization. The Z group is selected for its effect on the thiocarbonyl bond, where monomers are added. In some embodiments, then, the RAFT initiator may have the general structures illustrated below:

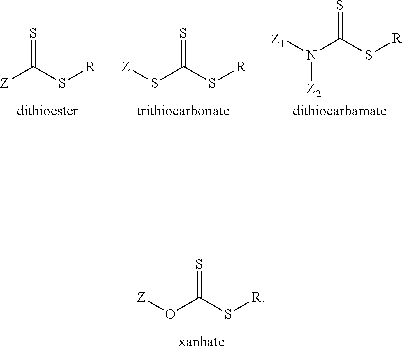

The Z group may be selected such that monomers are added to only one side of the thiocarbonyl group. For example, Z may be alkyl or aryl. The R group usually includes an electron-withdrawing group on the alpha carbon, for example, one or more alkyl groups or cyano groups.

In the RAFT initiators of the present disclosure, the R group also includes a reactive group which is capable of forming a covalent bond with a molecule that has the acid-labile group. The molecule with the acid-labile group usually also has two reactive groups. Examples of reactive groups that can form covalent bonds include thiols (—SH), hydroxy groups (—OH), and carboxyl groups (—COOH, —COOR), and acyl halides (—COX).

Conventional radical initiators may be used in the RAFT polymerization system. Non-limiting examples may include azobisisobutyronitrile (AIBN) and 4,4′-azobis(4-cyanovaleric acid) (ACVA).

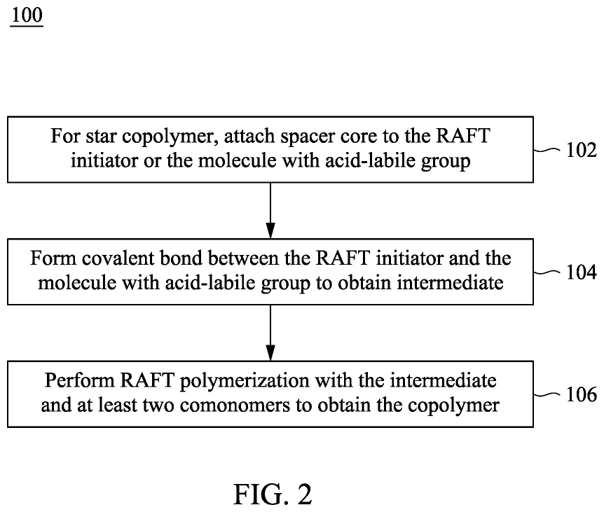

The RAFT polymerization process for forming the acid-cleavable copolymers of the present disclosure is very generally a two-step process. One such method 100 is described in FIG. 2.

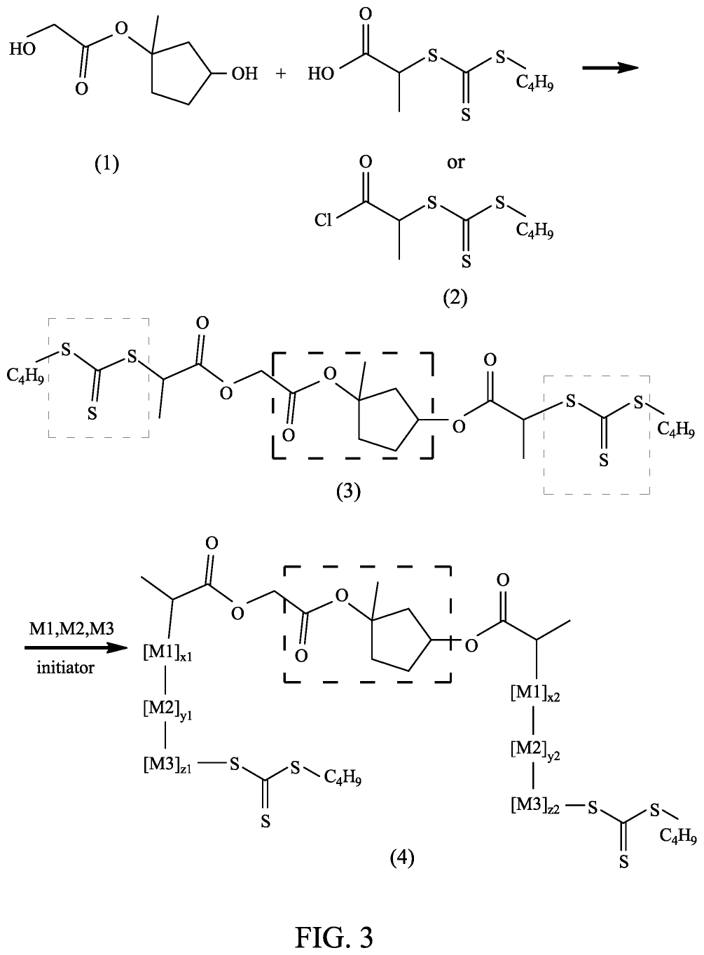

Initially, if a star copolymer is desired, then in step 102, the spacer core is reacted with either the RAFT initiator or the molecule with the acid-labile group. Next, in the first step of the process, as indicated in step 104, the RAFT initiator is reacted with the molecule that has the acid-labile group to form an intermediate. Then, in the second step of the process, as indicated in step 106, RAFT polymerization is performed with at least two comonomers. Four examples of this process are illustrated in FIGS. 3-7.

Referring first to FIG. 3, the molecule with the acid-labile group (1) has two reactive hydroxyl groups on either side of the acid-labile group. Here, the acid-labile group is an ester. In the first step, the molecule (1) is reacted with RAFT initiator (2), which has only one reactive group, either a carboxyl group or an acid halide, to form covalent bonds. The resulting intermediate (3) includes two RAFT chain transfer agents (indicated in dashed boxes) on either side of the acid-labile group (indicated in dotted box).

In the second step, the intermediate (3) is reacted with three comonomers M1, M2, and M3. These comonomers can be added at either RAFT chain transfer agent in amounts indicated as x1, y1, z1, x2, y2, z2, where x1+x2=x; y1+y2=y; and z1+z2=z as defined above with respect to Formulas (I)-(V). The resulting acid-cleavable copolymer (4) thus contains one acid-labile group, and the RAFT chain transfer agents may be considered end-caps. As an example, then, if the copolymer (4) had a molecular weight of 10,000 prior to radiation exposure, then after exposure the copolymer would split into two fragments each having a molecular weight of about 5,000.

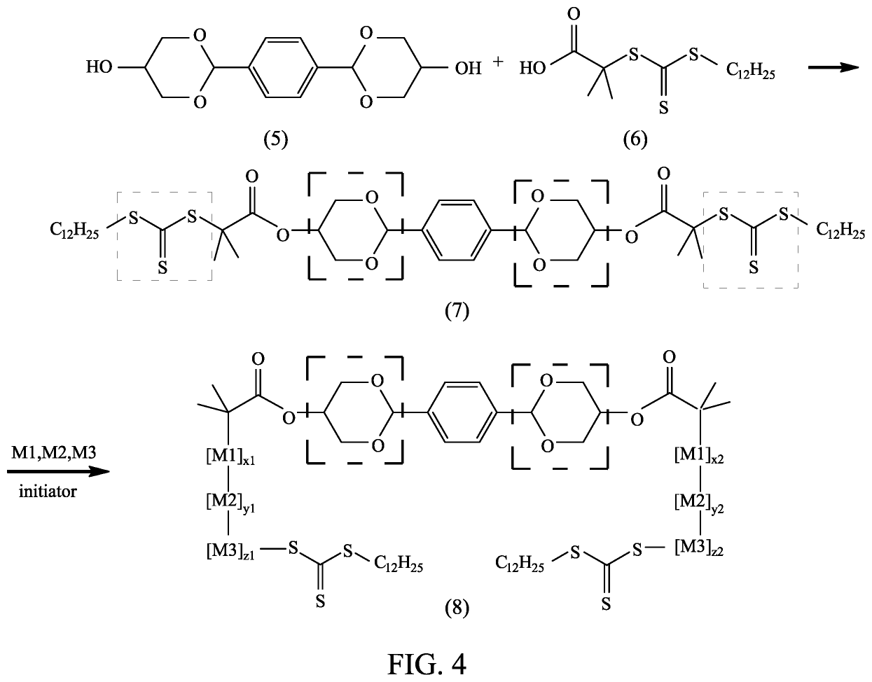

Referring now to FIG. 4, the molecule (5) has two acid-labile groups on either side of a phenyl group, and also has two reactive hydroxyl groups on either side of the acid-labile groups. In the first step, the molecule (5) is reacted with RAFT initiator (6), which again has only one reactive group. The resulting intermediate (7) includes two RAFT chain transfer agents (indicated in dashed boxes) on either side of the two acid-labile groups (indicated in dotted box).

In the second step, the intermediate (7) is reacted with three comonomers M1, M2, and M3. These comonomers can be added at either RAFT chain transfer agent. The resulting acid-cleavable copolymer (8) thus contains two acid-labile groups. Again, the RAFT chain transfer agents may be considered end-caps. If the copolymer (8) had a molecular weight of 10,000 prior to radiation exposure, then after exposure the copolymer would split into three fragments. Two fragments containing the comonomers would have a molecular weight of just less than 5,000. The third fragment would include the phenyl group, and would have a molecular weight of about 132 g/mol.

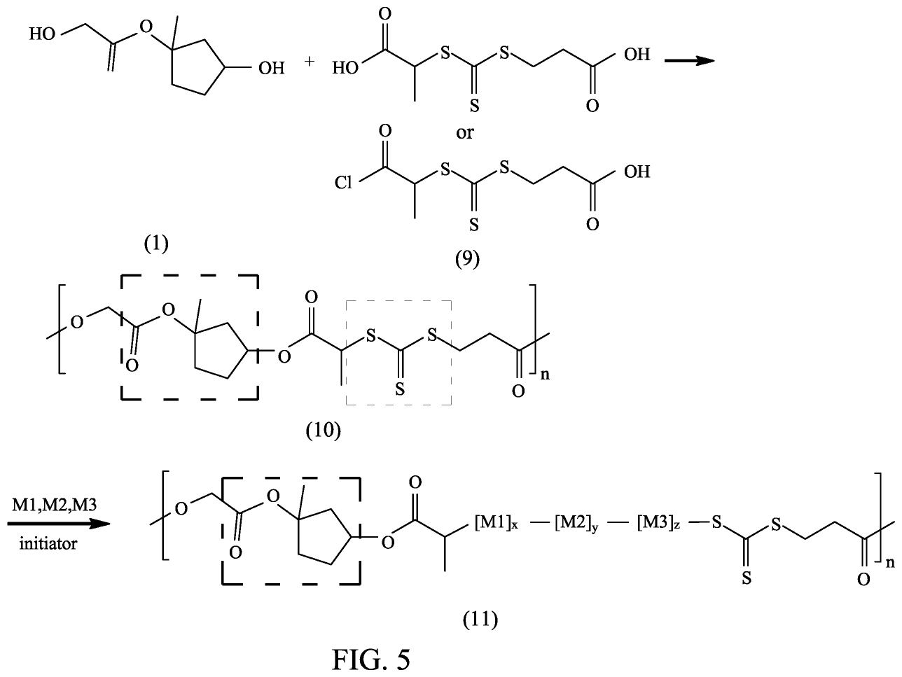

Referring now to FIG. 5, the molecule with the acid-labile group (1) is reacted with a RAFT initiator (9) that has two reactive groups. As a result, the intermediate (10) itself can be considered an oligomer, where n is from 2 to about 40. In the second step when the comonomers are added, then, the molecular weight of the oligomer increases. In this example, the resulting copolymer (11) includes n acid-labile groups. The copolymer (11) also includes n RAFT chain transfer units. If the copolymer (8) had a molecular weight of 10,000 prior to radiation exposure and was made of 10 oligomers (n=10), then after exposure the copolymer would split into 10 fragments, each having a molecular weight of about 1,000.

It should be noted that when the molecule (1) and the RAFT initiator (9) each have two reactive groups, in a star polymer, either the molecule (1) or the RAFT initiator (9) may be attached to the spacer core. This can be controlled by exposing the spacer core to the molecule (1) first, or by exposing the spacer core to the RAFT initiator (9) first. These two options are illustrated above in Formulas (IV) and (V).

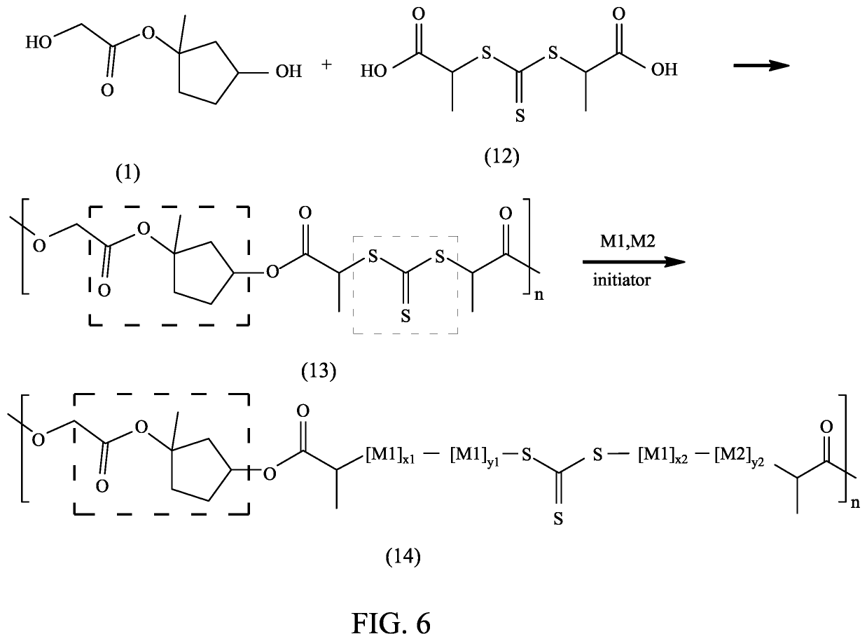

Referring now to FIG. 6, the molecule with the acid-labile group (1) is reacted with a RAFT initiator (12) that has two reactive groups to form intermediate (13). In this particular embodiment, the RAFT initiator (12) has an electron-withdrawing substituent on the alpha carbon on both sides of the thiocarbonyl group. Thus, in the second step, shown here with only two comonomers M1 and M2, the comonomers can be added to both sides of the RAFT chain transfer agent as illustrated here.

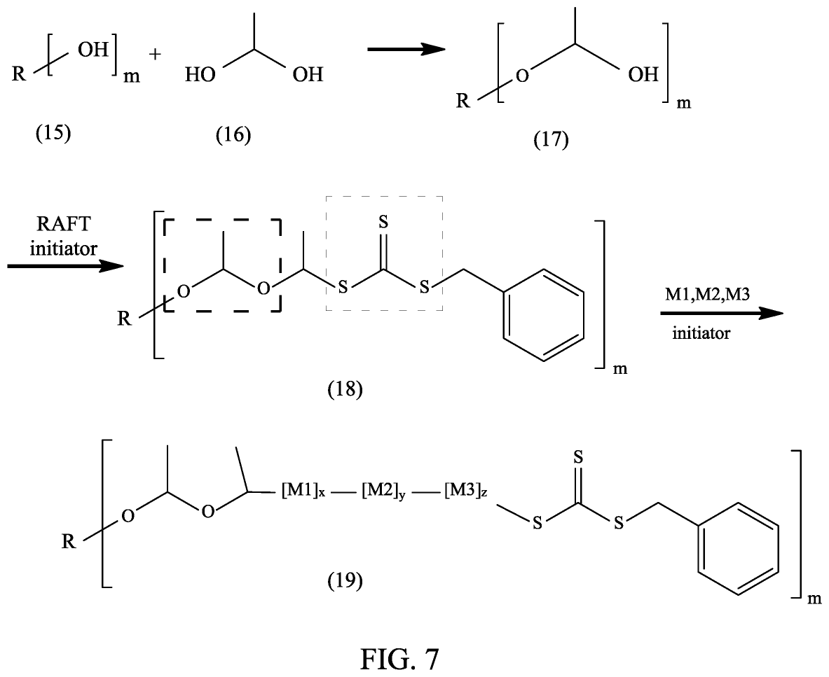

FIG. 7 is an illustrative example of a star copolymer. Here, all three steps of FIG. 2 are illustrated. The spacer core (15) is indicated with the letter R, and the number of arms of the star copolymer is indicated with the variable m. The molecule with an acid-labile group (16) is illustrated as an acetal. The spacer core (15) and molecule (16) are reacted to form a first intermediate (17). The RAFT initiator is then reacted with the acid-labile group of first intermediate (17) to obtain the second intermediate (18). In the second step when the comonomers are added, the molecular weight of each arm increases. In this illustration, the acid-labile group is attached to the spacer core and the RAFT chain transfer agent is acting as an end-cap on each arm. The resulting copolymer (19) includes m acid-labile groups. The copolymer (19) also includes m RAFT chain transfer units. If the copolymer (19) had a molecular weight of 6,000 prior to radiation exposure and had six oligomeric arms (m=6), then after exposure the copolymer would split into seven fragments. Six fragments would correspond to the arms, each having a molecular weight of just under 1,000. The seventh fragment would include the spacer core.

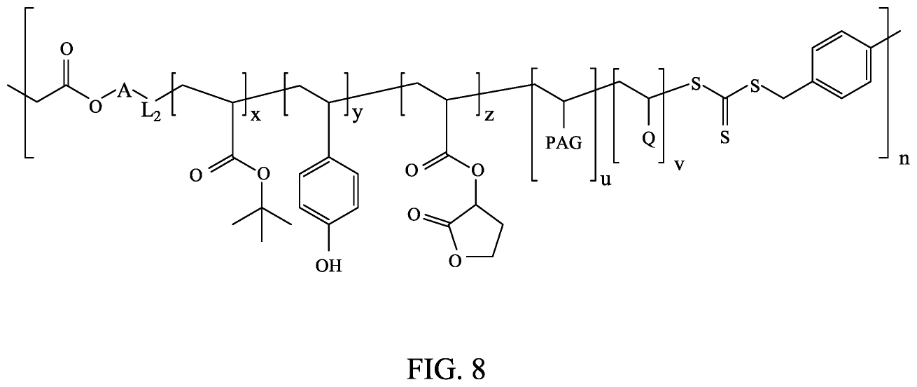

The copolymers of FIGS. 3-7 do not illustrate the fourth comonomer or the fifth comonomer. FIG. 8 is an illustration of a copolymer that does include the fourth comonomer (having the PAG pendant group) and the fifth comonomer (having the Q pendant group). In this illustration, the linking group L₂ includes an electron-withdrawing substituent that activates the thiocarbonyl group to direct the placement of the comonomers.

The acid-cleavable copolymer is, in particular embodiments, a positive-tone photoresist, which is photo-sensitive and is degraded by exposure to radiation. As a result, the developer will dissolve the regions that were exposed to light.

The acid-cleavable copolymer is one component of a photoresist composition. Other components of the photoresist composition may include a photoacid generator (PAG), a quencher, and a solvent. The PAG and quencher are particularly present if the acid-cleavable copolymer does not include the fourth comonomer or the fifth comonomer, respectively. Other optional additives may also be present in the photoresist composition, such as a surfactant, a sensitizer, a crosslinking agent, a stabilizer, a dissolution inhibitor, a plasticizer, a colorant, an adhesion promoter, and/or a surface leveling agent.

Non-limiting examples of PAGs may include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

Specific examples of PAGs include α-(trifluoromethylsulfonyloxy)-bicyclo[2.2.1]hept-5-ene-2,3-dicarboximide (MDT); N-hydroxy-naphthalimide (DDSN); benzoin tosylate; t-butylphenyl-α-(p-toluenesulfonyloxy)-acetate; t-butyl-α-(p-toluenesulfonyloxy)-acetate; triarylsulfonium and diaryliodonium hexafluoroantimonates; hexafluoroarsenates; trifluoromethanesulfonates; iodonium perfluorooctanesulfonate; N-camphorsulfonyloxynaphthalimide; N-pentafluorophenylsulfonyloxynaphthalimide; ionic iodonium sulfonates such as diaryl iodonium (alkyl or aryl) sulfonate and bis-(di-t-butylphenyl)iodonium camphanylsulfonate; such perfluoroalkanesulfonates as perfluoropentanesulfonate, perfluorooctanesulfonate, or perfluoromethanesulfonate; aryl triflates such as triphenylsulfonium triflate or bis-(t-butylphenyl)iodonium triflate; pyrogallol derivatives (e.g., trimesylate of pyrogallol); trifluoromethanesulfonate esters of hydroxyimides; α,α′-bis-sulfonyl-diazomethanes; sulfonate esters of nitro-substituted benzyl alcohols; naphthoquinone-4-diazides; ethanone; and alkyl disulfones.

A quencher can be used to inhibit diffusion of the generated acid within the photoresist, which improves the stability of the photoresist and also improves the resist pattern configuration. Non-limiting examples of quenchers include amines and organic acids. The amine may be a second lower aliphatic amine or a tertiary lower aliphatic amine. Specific examples of amine quenchers include trimethylamine; diethylamine; triethylamine; di-n-propylamine; tri-n-propylamine; tripentylamine; diethanolamine; triethanolamine; and other alkanolamine.

Examples of organic acids that can be used as quenchers may include malonic acid; citric acid; malic acid; succinic acid; benzoic acid; salicylic acid; phosphoric acid and derivatives thereof such as phosphoric acid di-n-butyl ester or phosphoric acid diphenyl ester; phosphonic acid and derivatives thereof such as phosphonic acid dimethyl ester, phosphonic acid di-n-butyl ester; phenylphosphonic acid, phosphonic acid diphenyl ester, or phosphonic acid dibenzyl ester; and phosphinic acid and derivatives thereof such as its esters or phenylphosphinic acid.

The various components are mixed or blended together in a solvent to form the photoresist composition. In particular embodiments, the solvent is an organic solvent. Examples of suitable organic solvents include propylene glycol monomethyl ether (PGME), propylene glycol methyl ether acetate (PGMEA), and mixtures of PGME and PGMEA commercially known as OK73. Other examples include ketones, alcohols, polyalcohols, ethers, glycol ethers, cyclic ethers, aromatic hydrocarbons, esters, propionates, lactates, lactic esters, alkylene glycol monoalkyl ethers, alkyl lactates, alkyl alkoxypropionates, cyclic lactones, monoketone compounds that contain a ring, alkylene carbonates, alkyl alkoxyacetate, alkyl pyruvates, lactate esters, ethylene glycol alkyl ether acetates, diethylene glycols, propylene glycol alkyl ether acetates, alkylene glycol alkyl ether esters, alkylene glycol monoalkyl esters, or the like.

A surfactant may be present in the photoresist composition. Upon development, the surfactant may facilitate the removal of residues from the photoresist layer. The surfactant may be an alkyl cationic surfactant, an amide-type quaternary cationic surfactant, an ester-type quaternary cationic surfactant, an amine oxide surfactant, a betaine surfactant, an alkoxylate surfactant, a fatty acid ester surfactant, an amide surfactant, an alcohol surfactant, an ethylenediamine surfactant, or a fluorine- and/or silicon-containing surfactant.

A sensitizer may be present in the photoresist composition. Upon irradiation, the sensitizer is designed to generate radiation of a different wavelength, such that the sensitivity of the photoresist material is substantially improved. In some embodiments, the sensitizer may include fluorine, a metal, or a phenol group. For example, the sensitizer may be polyhydroxystyrene (PHS) or polyfluorostyrene. Other sensitizers like organic iodides, bromides, chlorides, or magnesium-containing compounds which have a high electron-beam cross section could also be used.

A crosslinking agent may also be added to the photoresist composition. The cross-linking agent can react with the copolymer after exposure, assisting in increasing the cross-linking density of the photoresist, which helps to improve the resist pattern and resistance to etching. Examples of cross-linking agents can include melamines, ureas, glycoluril compounds, aliphatic hydrocarbons having hydroxyl or thiol or hydroxyalkyl groups, alcohols, and etherified amino resins.

A stabilizer may be included in the photoresist composition. The stabilizer reduces diffusion of the acids generated during exposure of the photoresist composition. Examples of stabilizers include nitrogenous compounds such as aliphatic primary, secondary, and tertiary amines; cyclic amines such as piperidines, pyrrolidines, and morpholines; aromatic heterocycles such as pyridines, pyrimidines, and purines; imines; guanidines; imides; amides; ammonium salts; cationic nitrogenous compounds; phenolates; carboxylates; aryl and alkyl sulfonates; sulfonamides; and the like.

A dissolution inhibitor may be included in the photoresist composition to help control dissolution of the photoresist during development. Non-limiting examples of dissolution inhibitors include cholic acid, deoxycholic acid, lithocholic acid, t-butyl deoxycholate, t-butyl lithocholate, and t-butyl-3-α-acetyl lithocholate.

A plasticizer may be used in the photoresist composition to reduce delamination and cracking between the photoresist and the underlying layer upon which the photoresist layer is formed. Examples of plasticizers may include monomeric, oligomeric, and polymeric plasticizers such as oligo- and polyethyleneglycol ethers, cycloaliphatic esters, and non-acid reactive steroidally-derived materials. Specific examples of materials that may be used for the plasticizer include dioctyl phthalate, didodecyl phthalate, triethylene glycol dicaprylate, dimethyl glycol phthalate, tricresyl phosphate, dioctyl adipate, dibutyl sebacate, triacetyl glycerine, and the like.

If desired, a colorant could be used to help in locating defects in the photoresist. Broad categories of colorants include dyes and pigments. More specific examples of colorants may include triarylmethane dyes, crystal violet, methyl violet, ethyl violet, malachite green, diamond green, phthalocyanine pigments, azo pigments, carbon black, titanium oxide, benzophenone compounds; salicylic acid compounds; phenylacrylate compounds; coumarin compounds; thioxanthone compounds; stilbene compounds; naphthalic acid compounds; azo dyes; and the like.

An adhesion promoter may be used in the photoresist composition to promote adhesion between the photoresist and the underlying layer upon which the photoresist layer is formed. Examples of adhesion promoters include silane compounds with at least one reactive substituent such as a carboxyl group, a methacryloyl group, an isocyanate group and/or an epoxy group.

Surface leveling agents may additionally be added to the photoresist composition, for leveling the top surface of the photoresist layer. Examples of surface leveling agents include fluoroaliphatic esters, hydroxyl terminated fluorinated polyethers, fluorinated ethylene glycol polymers, silicones, and acrylic polymer leveling agents.

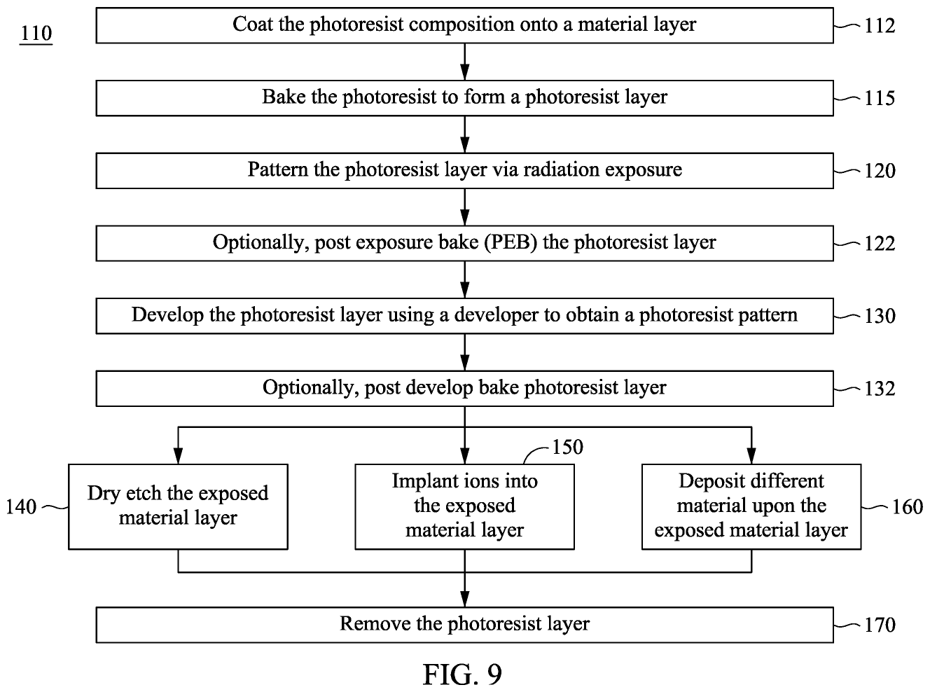

The photoresist composition is used to form a photoresist layer that is used in various methods for forming various structures in an integrated circuit or semiconductor device. One such method 110 for forming a photoresist pattern and patterning a material layer in a semiconductor device is described in FIG. 9.

Initially, it may be desirable to heat the substrate prior to beginning the photoresist patterning process. This may improve resist adhesion by desorbing water present on the substrate surface and to thermally crack any hydroxide bonds present on an oxidized surface. The substrate can be heated to temperatures above 100° C. up to, for example, 200° C. for a period of several minutes. The substrate is then cooled back down to room temperature.

In step 112, the photoresist composition is coated onto a substrate. It is noted that the substrate may be any type of material layer in which a pattern is desired to be formed. The coating may be done, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

In step 115, the photoresist composition is baked or cured to remove the solvent and harden the photoresist layer. In some particular embodiments, the baking occurs at a temperature of about 80° C. to about 110° C., and for a time period of about 60 seconds. The baking can be performed using a hot plate or oven, or similar equipment.

In step 120, the photoresist layer is patterned via exposure to radiation. The radiation may be any light wavelength which carries a desired mask pattern, although ultraviolet (“UV”) radiation is typically used at the current time. UV radiation has a wavelength in the range of about 10 nanometers (“nm”) to about 400 nm, such as from KrF lasers (248 nm) or ArF lasers (193 nm). In particular embodiments, extreme ultraviolet (“EUV”) light having a wavelength of about 13.5 nm is used for patterning, as this permits smaller feature sizes to be obtained. In other embodiments, e-beam radiation is used. This results in some portions of the photoresist layer being exposed to radiation, and some portions of the photoresist not being exposed to radiation. This exposure activates the acid-cleavable copolymer, such that some portions of the photoresist will be soluble in the developer and some portions of the photoresist will not be soluble in the developer.

In optional step 122, an additional photoresist bake step (post exposure bake, or PEB) may occur after the exposure to radiation. This may help in releasing the acid labile groups (ALGs) or other molecules that are significant in chemical amplification.

In step 130, the photoresist layer is developed using a developer. The developer may be an aqueous solution or an organic solution. The soluble portions of the photoresist layer are dissolved and washed away during the development step, leaving behind a photoresist pattern. One example of a common developer for positive-tone photoresist is aqueous tetramethylammonium hydroxide (TMAH). Generally, any suitable developer may be used.

In optional step 132, a post develop bake or “hard bake” may be performed to stabilize the photoresist pattern, for optimum performance in subsequent steps.

Continuing, portions of the material layer below the photoresist pattern are now exposed. In step 140, the material layer is etched, causing the exposed portions of the material layer to be removed, thus transferring the photoresist pattern to the material layer. In particular embodiments, the etching is performed by dry etching.

Besides etching of the material layer, other process steps may alternatively be carried out. For example, in alternative step 150, ions may be implanted into the exposed material layer instead, or as in alternative step 160, a different material can be deposited upon the material layer.

Finally, in step 170, the photoresist layer can then be removed. This can be done, for example, using various solvents such as N-methyl-pyrrolidone (NMP) or alkaline media or other strippers at elevated temperatures, or by dry etching using oxygen plasma.

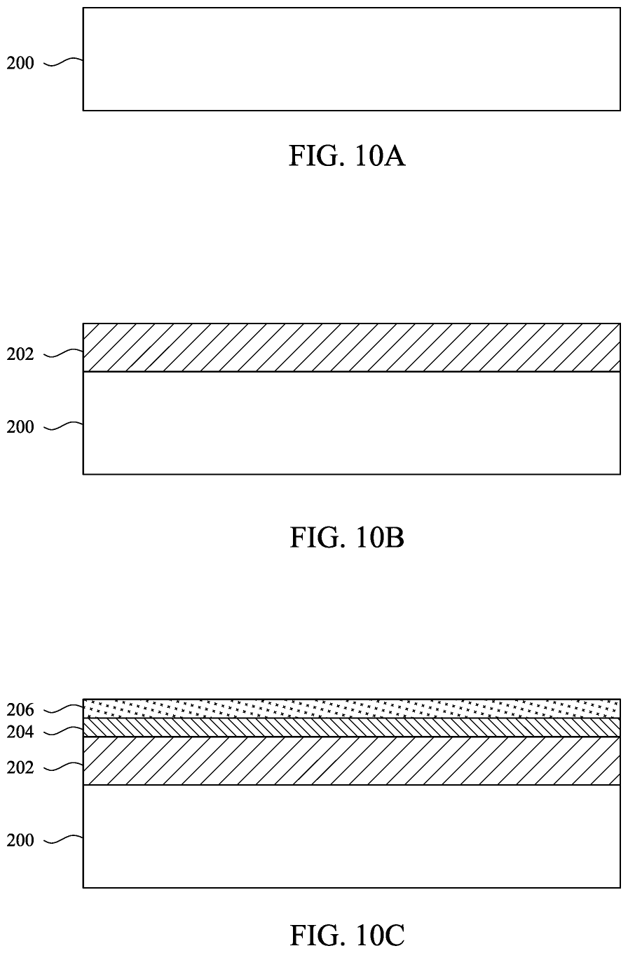

FIGS. 10A-14 illustrate various aspects of the method of FIG. 9. These figures provide different views for better understanding.

Referring first to FIG. 10A, this figure shows one example of the beginning state of the substrate 200 prior to any processing steps. The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon. As illustrated here, no additional layers are present upon the substrate 200.

In contrast, in FIG. 10B, a first material layer 202 is present upon the substrate 200. The first material layer may be any material that may be used in a semiconducting device or integrated circuit. For example, the first material layer could be made of an insulating material, such as silicon dioxide (SiO₂) or silicon nitride (SiN), silicon oxynitride (SiON), fluoride-doped silicate glass, or other dielectric material. As another example, the first material layer could be made of an electrically conductive material, such as polysilicon or a metal like aluminum, copper, titanium, or tungsten. The first material layer may generally serve any function. For example, the first material layer could be a high-k dielectric layer, a gate layer, a hard mask layer, an interfacial layer, a capping layer, a diffusion/barrier layer, a dielectric layer (e.g. SiO₂), a conductive layer (e.g. doped polysilicon), or some other layer. The figures below show a first material layer being present, for illustrative purposes only and with it being understood that the substrate can also be etched.

In FIG. 10C, one or more underlayers have been applied to the substrate prior to the photoresist composition being applied. In this regard, the term “underlayer” is relative to the photoresist layer, and refers to any layers which may be applied to the layer that is desired to be etched prior to applying the photoresist composition. Put another way, any layers between the layer to be etched and the photoresist layer can be considered an underlayer. In this illustration, two underlayers 204, 206 are applied upon the first material layer 202.

As one example, the lower underlayer 204 may be a bottom anti-reflective coating (BARC). When a photoresist layer is applied to a reflective substrate, light reflection from the substrate/resist interface can create variations in light exposure, that cause problems with critical dimension (CD) control. For example, light can reflect into areas where exposure was not intended, changing the desired pattern. A BARC can be applied between the substrate and the photoresist layer to minimize or eliminate such problems. Examples of suitable BARCs include amorphous carbon and various organic polymers. The BARC layer is typically formed by spin coating, though other methods can also be used. The BARC coating or film is then baked or cured to induce crosslinking and solvent removal, and hardening of the BARC. In some particular embodiments, the baking occurs at a temperature of about 125° C. to about 275° C. In particular embodiments, the baking takes place for a time of about 30 seconds to about 250 seconds. The baking can be performed using a hot plate or similar equipment.

As another example, the upper underlayer 206 may be a hard mask layer. The hard mask layer may be formed from a dielectric material, a metal, or other suitable material. Examples of suitable dielectric materials may include silicon carbide, silicon nitride, silicon oxycarbide, or silicon oxynitride. The hard mask layer may be formed by any suitable process such as chemical vapor deposition (CVD), low-pressure CVD (LPCVD), plasma-enhanced CVD (PECVD), physical vapor deposition (PVD), atomic layer deposition (ALD), or spin coating. The BARC layer and the hard mask layer are also typically selected to have significantly different etching sensitivity towards the same etchant. Combined with the photoresist layer, this multi-layer resist pattern can also help improve line width roughness (LWR).

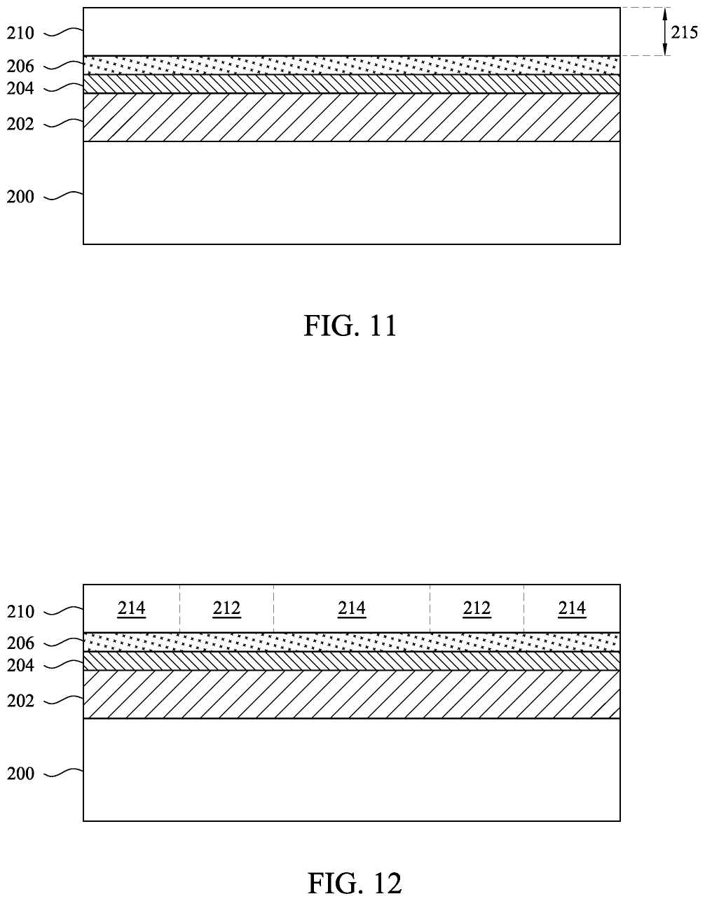

Now, beginning with step 105 of FIG. 9 and as illustrated in FIG. 11, the photoresist composition is applied over the substrate, and onto a material layer such as underlayer 206. The photoresist composition may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist composition evenly from the center of the substrate to the perimeter of the substrate. The rotating speed of the platen is then fixed, which can control the thickness of the final photoresist layer.

Next, in step 110 of FIG. 9 and referring still to FIG. 11, the photoresist composition is prebaked to remove the solvent and harden the photoresist layer. This may also be referred to as a softbake. In some particular embodiments, the prebake occurs at a temperature of about 40° C. to about 100° C., including from about 250° C. to about 800° C. or from about 80° C. to about 110° C. The time for the prebake may depend upon the thickness of the photoresist layer, with longer times for greater thicknesses, and in particular embodiments from about 10 seconds to about 10 minutes. The baking can be performed using a hot plate or oven, or similar equipment. Referring to FIG. 11, the photoresist layer 210 may have a thickness 215 of about 10 nanometers to about 100 nanometers. The substrate and the other layers thereon are then cooled down to room temperature.

Continuing, in step 120 of FIG. 9, the photoresist layer 210 is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. In other embodiments, electron-beam (e-beam) radiation is used. Electron beams can be characterized by the energy of the beam, which in some embodiments ranges from about 5 kilovolts (kV) to about 200 kV. This step results in some portions of the photoresist layer being exposed to radiation, and some portions of the photoresist not being exposed to radiation. This exposure causes some portions of the photoresist to remain soluble in the developer and other portions of the photoresist to become insoluble in the developer. Referring now to FIG. 12, the photoresist layer 210 now includes soluble regions 212 and insoluble regions 214. It is noted for reference that EUV and e-beam radiation exposure typically occur under vacuum.

Optionally, in step 122 of FIG. 9, a post exposure bake (PEB) occurs after the exposure to radiation. The PEB step can be used to complete any cross-linking within the photoresist, or to complete any chemically amplified reactions that may occur. In addition, the PEB step may reduce mechanical stress that might build up during the prior steps. In some particular embodiments, the PEB occurs at a temperature of about 40° C. to about 250° C., including from about 100° C. to about 250° C. or from about 90° C. to about 150° C. The time for the PEB may range from about 10 seconds to about 10 minutes, and may vary depending on the thickness of the photoresist layer.

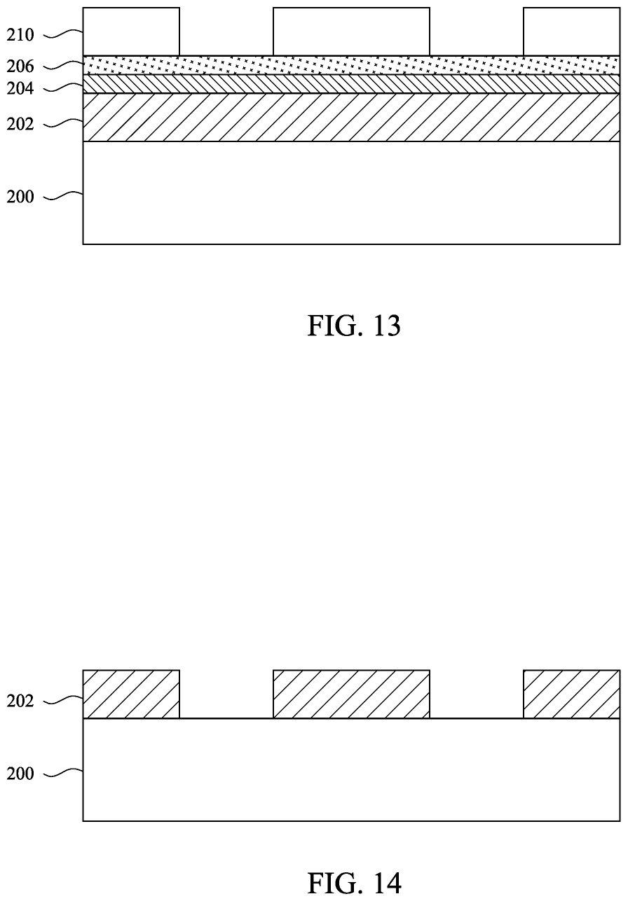

Next, in step 130 of FIG. 9, the photoresist layer 210 is developed using a developer. The developer may be applied by spin coating, spraying, or other suitable process. The soluble portions of the photoresist layer are dissolved and washed away during the development step, leaving behind a patterned photoresist layer. This may be done, for example, by spin drying. The resulting structure is illustrated in FIG. 13. As seen here, the soluble regions have been washed away, resulting in a patterned photoresist layer.

In optional step 132 of FIG. 9, a post develop bake or “hardbake” may be performed after development. This can be done to stabilize the photoresist pattern after development, for optimum performance in subsequent steps. In some particular embodiments, the hardbake occurs at a temperature of about 100° C. to about 160° C. The time for the hardbake may range from about 1 minute to about 10 minutes, and may vary depending on the thickness of the photoresist layer.

Continuing, then, as seen in FIG. 13, portions of the upper underlayer 206, the lower underlayer 204, and the first material layer 202 below the patterned photoresist layer are now exposed.

Then, in step 140 of FIG. 9, etching is performed through the patterned photoresist layer to transfer the photoresist pattern through the underlayers 206, 204 to the first material layer 202 and obtain a patterned material layer. Desirably, each of the etchants for the various layers differs significantly from that of the other layers, which improves the LWR in the first material layer. It should be understood that the patterned material layer can be either the first material layer or the substrate as well. In some embodiments, the first material layer is an insulating layer, and the etched pattern may subsequently be filled with a conductive material to form a circuit within this insulating layer. In other alternate embodiments, the first material layer is a conductive layer, and the etched pattern is subsequently filled with an insulating material.

Generally, these etching steps may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Besides etching of the first material layer, other process steps may alternatively be carried out. For example, in alternative step 150, ions may be implanted into the exposed material layer instead, or as in alternative step 160, a different material can be deposited upon the material layer.

Next, in step 170 of FIG. 9, the patterned photoresist layer 210 is removed. The underlayers are also removed. The photoresist layer, the upper underlayer, and the lower underlayer can be removed using conventional means such as plasma stripping, solvent, or chemical-mechanical planarization (CMP). The resulting structure is illustrated in FIG. 14, with the first material layer 202 being patterned.

The use of the acid-cleavable copolymer in the photoresist composition provides many advantages. Prior to radiation exposure, the acid-cleavable copolymer has a high molecular weight, which improves the quality of the photoresist coating when applied to the substrate. After radiation exposure, the copolymer is cleaved into fragments of significantly reduced molecular weight. This improves the line edge roughness (LER), line width roughness (LWR), and critical dimension uniformity (CDU), and the quality of the etched feature. This can also improve throughput, reducing overall cost.

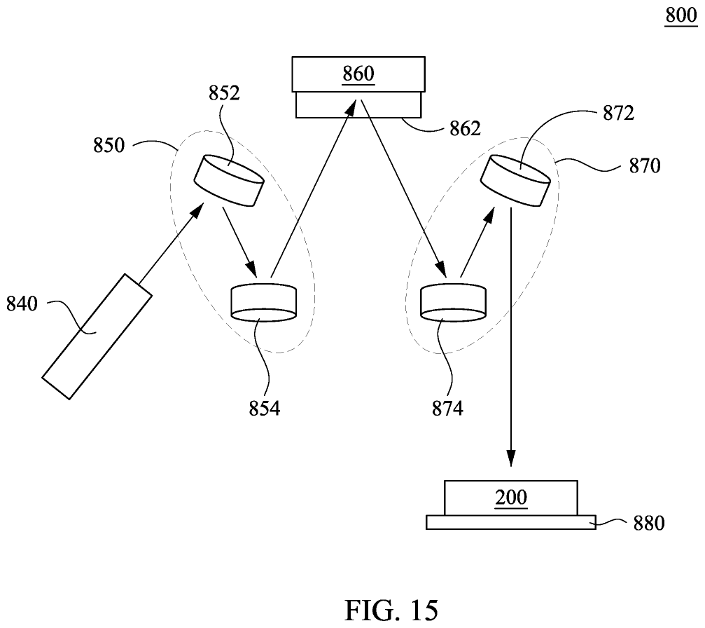

FIG. 15 is an illustrative schematic diagram, not drawn to scale, illustrating the various components of an extreme ultraviolet (EUV) photolithography system which generates the radiation to which the photoresist is exposed. Generally, the EUV photolithography system 800 begins with an EUV light source 840 that generates EUV light or radiation. Downstream of the EUV light source is an illumination stage 850 in which the EUV light may be collected and focused as a beam, for example using field facet mirror 852 that splits the beam into a plurality of light channels. These light channels can then directed using one or more relay mirrors 854 onto the plane of the photomask. The photomask 860 may include a pellicle membrane 862, through which the radiation passes before and/or after contacting the photomask. Downstream of the photomask 860 is the projection optics module 870, which is configured for imaging the pattern of the photomask onto the semiconductor wafer substrate 200. The projection optics module 870 may include refractive optics or reflective optics for carrying the image of the pattern defined by the photomask. Illustrative mirrors 872, 874 are shown. The wafer substrate 200 is positioned upon a wafer stage 880, which can move as necessary for imaging. The lithography system can include other modules or be integrated with or coupled to other modules.

Additional processing steps may be performed to fabricate a semiconductor device or integrated circuit. Examples of such steps may include ion implantation, deposition of other materials, etching, etc.

Some aspects of the present disclosure thus relate to methods for forming a photoresist pattern. A substrate is coated with a photoresist composition comprising an acid-cleavable copolymer to form a photoresist layer. The photoresist layer is exposed to radiation to pattern the photoresist layer. The exposure releases acid that causes a backbone or an arm of the copolymer to be cleaved. Optionally, a post-exposure bake of the coated substrate is performed. The patterned photoresist layer is developed using a developer. Optionally, the patterned photoresist layer can be hard baked. Etching can be performed through the patterned photoresist layer to obtain a patterned material layer upon the substrate.

Also disclosed in various embodiments are photoresist compositions, comprising: an acid-cleavable copolymer having acid-labile groups in a backbone or an arm of the copolymer; a photoacid generator; and a quencher. A solvent may also be present if needed.

Also disclosed herein are methods for forming an acid-cleavable copolymer. A covalent bond is formed between a RAFT initiator and a molecule that has an acid-labile group to obtain an intermediate. RAFT polymerization is then performed with (A) a first comonomer and (B) at least one of (i) a second comonomer or (ii) a third comonomer to obtain the copolymer. The first comonomer has an acidic leaving substituent, the second comonomer has a proton donating substituent, and the third comonomer has a polar substituent.

Also disclosed are acid-cleavable copolymers. The acid-cleavable copolymer includes oligomers in the backbone or the arm of the copolymer. Each oligomer comprises: an acid-labile group; a first comonomer having an acidic leaving substituent; and at least one of (i) a second comonomer having a proton donating substituent or (ii) a third comonomer having a polar substituent.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a photoresist pattern, comprising:
coating a substrate with a photoresist composition comprising an acid-cleavable copolymer to form a photoresist layer;
exposing the photoresist layer to radiation to pattern the photoresist layer, wherein the exposure releases acid that causes a backbone or an arm of the copolymer to be cleaved;
optionally performing a post-exposure bake of the coated substrate;
developing the patterned photoresist layer using a developer; and
optionally hard baking the patterned photoresist layer.

2. The method of claim 1, wherein the acid-cleavable copolymer includes oligomers in the backbone or the arm of the copolymer, each oligomer comprising:
an acid-labile group;
a first comonomer having an acidic leaving substituent; and
at least one of a second comonomer having a proton donating substituent or a third comonomer having a polar substituent.

3. The method of claim 2, wherein:
a molar ratio of the first comonomer is from about 15% to about 70% of the oligomer;
a molar ratio of the second comonomer, when present, is up to about 50% of the oligomer; and
a molar ratio of the third comonomer, when present, is up to about 70% of the oligomer.

4. The method of claim 2, wherein the acid-labile group is an ester, an amide, an acetal, an imine, a hydrazone, or an oxime.

5. The method of claim 2, wherein the copolymer has 2 to 40 oligomers in the backbone or the arm.

6. The method of claim 2, wherein each oligomer further comprises a RAFT chain transfer agent.

7. The method of claim 6, wherein the RAFT chain transfer agent is a dithioester, a trithiocarbonate, a dithiocarbamate, or a xanthate.

8. The method of claim 2, wherein the first comonomer is an alkyl acrylate or an aryl acrylate.

9. The method of claim 2, wherein the second comonomer is styrene with one or more hydroxy, ether, ester, or carboxy substituents.

10. The method of claim 2, wherein the third comonomer is an acrylate with a polar substituent.

11. The method of claim 10, wherein the polar substituent contains one or more oxygen atoms, or is a lactone.

12. The method of claim 2, wherein each oligomer further comprises a fourth monomer having a photoacid generating substituent and/or a fifth monomer having a quenching substituent.

13. The method of claim 12, wherein a molar ratio of the fourth monomer is up to about 30% of the oligomer, and/or a molar ratio of the fifth monomer is up to about 30% of the oligomer.

14. The method of claim 2, wherein the copolymer has an end-cap formed from a RAFT chain transfer agent.

15. The method of claim 2, wherein the copolymer is a linear copolymer or a star copolymer.

16. A photoresist composition, comprising:
an acid-cleavable copolymer having acid-labile groups in a backbone or an arm of the copolymer; and
a photoacid generator; and
a quencher.

17. The photoresist composition of claim 16, wherein the copolymer further comprises a first comonomer and at least one of a second comonomer or a third comonomer;
wherein the first comonomer has an acidic leaving substituent, the second comonomer has a proton donating substituent, and the third comonomer has a polar substituent.

18. A method for forming an acid-cleavable copolymer, comprising:
forming a covalent bond between a RAFT initiator and a molecule that has an acid-labile group to obtain an intermediate; and
performing RAFT polymerization with the intermediate, a first comonomer, and at least one of a second comonomer or a third comonomer to obtain the copolymer;
wherein the first comonomer has an acidic leaving substituent, the second comonomer has a proton donating substituent, and the third comonomer has a polar substituent.

19. The method of claim 18, wherein the molecule that has the acid-labile group is attached to a spacer core.

20. The method of claim 18, wherein the RAFT initiator has two reactive groups, such that the intermediate is a copolymer.
